(19) United States
(12) Patent Application Publication
(10) Pub. No.: US 2023/0294209 A1
(43) Pub. Date: Sep. 21, 2023

(54) LASER ETCHING APPARATUS AND LASER ETCHING METHOD USING THE SAME

(71) Applicant: Samsung Display Co., Ltd., Yongin-si (KR)

(72) Inventors: Heungyeol NA, Suwon-si (KR); Yoonchul KIM, Cheonan-si (KR); Seong Jin YEON, Yongin-si (KR); Jungwoo CHOI, Asan-si (KR)

(21) Appl. No.: 18/097,122

(22) Filed: Jan. 13, 2023

(30) Foreign Application Priority Data
Mar. 15, 2022 (KR) 10-2022-0032092

(51) Int. Cl. B23K 26/362

(52) U.S. Cl. CPC B23K 26/362

(57) ABSTRACT

A laser etching method include performing a first emission process by emitting a laser beam from a laser module toward a substrate fastened to a chuck in a laser etching chamber, moving a protection window between the chuck and the laser module in a first direction by a first distance after the performing the first emission process, performing a second emission process by emitting a laser beam from the laser module after the moving the protection window in the first direction by the first distance, moving the protection window in an opposite direction of the first direction by a second distance after the performing the second emission process, and performing a third emission process by emitting a laser beam from the laser module after the moving the protection window in the opposite direction of the first direction by the second distance.

This application claims priority to Korean Patent Application No. 10-2022-0032092, filed on Mar. 15, 2022, and all the benefits accruing therefrom under 35 U.S.C. §119, the content of which in its entirety is herein incorporated by reference.

### BACKGROUND

### 1. Field

The disclosure relates to a laser etching apparatus and a laser etching method using the laser etching apparatus.

### 2. Description of the Related Art

Electronic products, such as a smart phone, a digital camera, a laptop computer, a navigation system, and a smart television may include a display device that is configured to display an image to a user. The display device is configured to generate an image and to provide the image to a user through a display screen. The display device may be fabricated through various processes. For example, the fabrication of the display device may include forming a hole in a portion of a display device using a laser etching apparatus.

### SUMMARY

In a fabrication of a display device, a laser etching apparatus may be used in an etching process of forming a hole in a substrate thereof using a laser beam. During the process of forming the hole, particles may be produced to cause a problem in a subsequent fabrication process. Thus, a protection window may be used to capture the particle. Particles, which are produced from the substrate, may be piled up on the protection window, and thus, it is desired to replace the protection window every replacement period.

An embodiment of the invention provides a laser etching apparatus, which is configured to allow for an increase of a replacement period of a protection window, and a laser etching method performed using the laser etching apparatus.

According to an embodiment of the invention, a laser etching method includes performing a first emission process by emitting a laser beam from a laser module toward a substrate fastened to a chuck in a laser etching chamber, moving a protection window between the chuck and the laser module in a first direction by a first distance after the performing the first emission process, performing a second emission process by emitting a laser beam from the laser module after the moving the protection window in the first direction by the first distance, moving the protection window in an opposite direction of the first direction by a second distance after the performing the second emission process, and performing a third emission process by emitting a laser beam from the laser module after the moving the protection window in the opposite direction of the first direction by the second distance.

According to an embodiment of the invention, a laser etching method includes loading a substrate in a laser etching apparatus, performing a first emission process by emitting a laser beam from a laser module toward the substrate, and moving a protection window between the substrate and the laser module during the performing the first emission process of the laser beam.

According to an embodiment of the invention, a laser etching apparatus includes a laser etching chamber, a chuck disposed in the laser etching chamber, a laser module which emits a laser beam toward the chuck, a protection window between the chuck and the laser module, a tray which supports the protection window, a linear motion unit which moves the tray in a first direction, and a position sensor which senses a position of the protection window.

### BRIEF DESCRIPTION OF THE DRAWINGS

FIG. 1 is a sectional view illustrating a laser etching apparatus according to an embodiment of the invention.

FIG. 2 is a plan view illustrating a portion of a laser etching apparatus according to an embodiment of the invention.

FIG. 3 is a flow chart illustrating a laser etching method according to an embodiment of the invention.

FIGS. 4 to 17 are diagrams sequentially illustrating processes of the laser etching method shown in the flow chart of FIG. 3.

FIGS. 18 and 19 are diagrams sequentially illustrating processes of the laser etching method shown in the flow chart of FIG. 3.

FIG. 20 is a flow chart illustrating a laser etching method according to an embodiment of the invention.

FIGS. 21 to 26 are diagrams sequentially illustrating processes of the laser etching method shown in the flow chart of FIG. 20.

FIG. 27 is a diagram illustrating the laser etching method shown in the flow chart of FIG. 20.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like reference numerals in the drawings denote like elements, and thus any repetitive detailed description thereof may be omitted or simplified.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, processes, operations, elements, and/or components, but do not preclude the presence or addition of one or more other features, regions, integers, processes, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

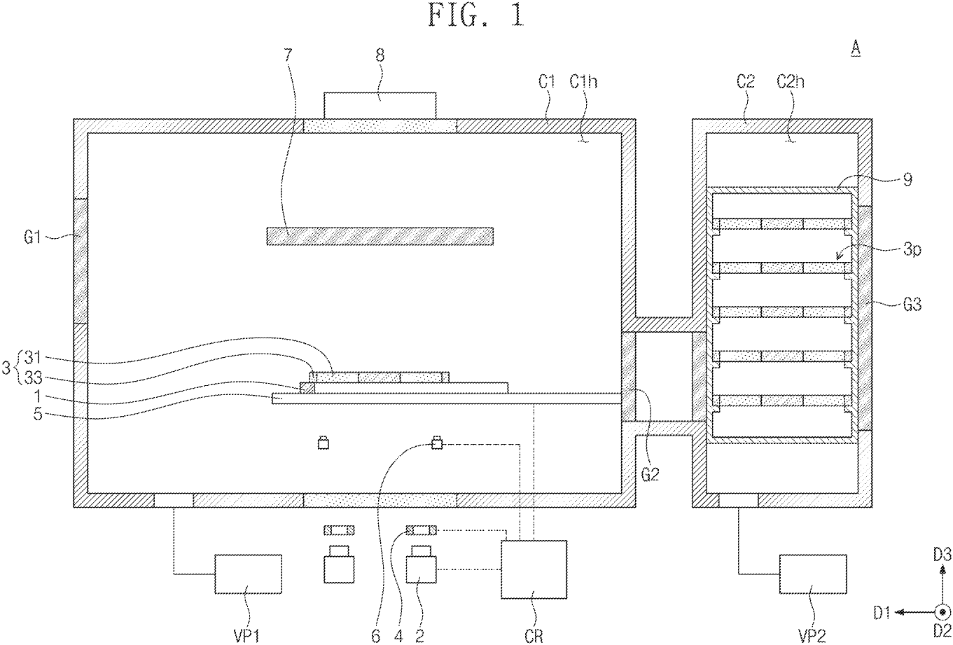

FIG. 1 is a sectional view illustrating a laser etching apparatus according to an embodiment of the invention.

In the disclosure, as shown in FIG. 1, the reference numbers D1, D2, and D3 will be used to denote a first direction, a second direction, and a third direction, respectively, which are not parallel to each other. Each of the first and second directions D1 and D2 may be referred to as a horizontal direction. In addition, the third direction D3 may be referred to as a vertical direction.

Referring to FIG. 1, a laser etching apparatus A may be provided. The laser etching apparatus A may be used to etch a surface of a substrate. More specifically, the laser etching apparatus A may be an apparatus of forming a hole in the surface of the substrate using a laser beam. In an embodiment, the laser etching apparatus A may include a laser etching chamber C1, a chuck 7, a laser module 2, an output sensing unit 8, a protection window assembly 3, a shuttle 1, a linear motion unit 5, an output adjustment unit 4, a position sensor 6, a protection window replacement chamber C2, a protection window storing stage 9, a first vacuum pump VP1, a second vacuum pump VP2, and a control unit CR.

The laser etching chamber C1 may define an etching space C1h. An etching process on the substrate may be performed in the etching space C1h. The etching space C1h may be selectively isolated from an outer space by a first door G1. In an embodiment, the first door G1 may be opened or closed to connect or isolate the etching space C1h to or from the outer space. The etching space C1h may be connected to the first vacuum pump VP1. During a fabrication process, the etching space C1h may be in a vacuum state by the first vacuum pump VP1.

The chuck 7 may be placed in the laser etching chamber C1. The chuck 7 may be configured to fasten the substrate at a specific position. In an embodiment, for example, the chuck 7 may fasten the substrate to a bottom surface of the chuck 7 using an electrostatic force. In such an embodiment, the chuck 7 may be an electrostatic chuck (ESC). However, the invention is not limited to this example, and in an alternative embodiment, the chuck 7 may include a vacuum chuck and/or an adhesion chuck. In an alternative, the substrate may be disposed on a top surface of the chuck 7. The chuck 7 may be configured to be movable in a horizontal direction. In an embodiment, for example, during a process of loading or unloading the substrate, the chuck 7 may be moved to the outer space of the laser etching chamber C1 through the first door G1. In addition, during an etching process, the chuck 7, on which the substrate is loaded, may be moved in the horizontal direction. This will be described in greater detail below.

The laser module 2 may be configured to emit a laser beam toward the chuck 7. In an embodiment, the laser module 2 may emit the laser beam toward a surface of the substrate, which is fastened by the chuck 7, and in this case, the surface of the substrate may be etched. The laser module 2 may be placed below the chuck 7. In such an embodiment, the laser module 2 may be configured to emit the laser beam in an upward direction. However, the invention is not limited to this example, and in an alternative embodiment, the laser module 2 may be placed above the chuck 7 and may emit the laser beam in a downward direction. In an embodiment, the laser module 2 may be placed outside the laser etching chamber C1. In an embodiment, for example, as illustrated in FIG. 1, the laser module 2 may be placed below the laser etching chamber C1, and in such an embodiment, the laser beam may be incident into the etching space C1h through a window (not referenced), which is formed in a bottom surface of the laser etching chamber C1. However, the invention is not limited to this example, and in an alternative embodiment, the laser module 2 may be placed within the etching space C1h. In an embodiment, a plurality of laser modules 2 may be provided. The laser modules 2 may be spaced apart from each other in the horizontal direction. Hereinafter, for convenience in description, embodiments, in which a single laser module 2 is provided, will be described in detail.

The output sensing unit 8 may measure an output of the laser beam, which is emitted from the laser module 2. In an embodiment, the output sensing unit 8 may include a laser power meter or the like. The output sensing unit 8 may be placed in an opposite region of the laser module 2, based on the chuck 7. In such an embodiment, the chuck 7 may be disposed between the output sensing unit 8 and the laser module 2. In an embodiment, for example, where the laser module 2 is placed below the laser etching chamber C1, the output sensing unit 8 may be placed above the laser etching chamber C1.

The protection window assembly 3 may be placed between the chuck 7 and the laser module 2. In an embodiment, the protection window assembly 3 may be placed between the substrate, which is fastened by the chuck 7, and the laser module 2. The protection window assembly 3 may be configured to be movable in the horizontal direction. In an embodiment, for example, the protection window assembly 3 may be configured to be movable, in the first direction D1 and an opposite direction of the first direction D1, by the linear motion unit 5. The protection window assembly 3 may be replaced every replacement period. In such an embodiment, one or more preliminary protection window assemblies 3p may be stored in the protection window storing stage 9. The protection window assembly 3 may include a protection window 31 and a tray 33.

The protection window 31 may be placed between the chuck 7 and the laser module 2. The laser beam emitted from the laser module 2 may be incident into the substrate, which is fastened to the chuck 7, through the protection window 31. The protection window 31 may be formed of or include a material having high transmittance to the laser beam. In an embodiment, for example, the protection window 31 may be formed of or include glass. In an embodiment, a plurality of protection windows 31 may be provided. The protection windows 31 may be disposed to be spaced apart from each other in the horizontal direction. This will be described in greater detail below.

The tray 33 may support the protection window 31. In an embodiment, for example, as illustrated in FIG. 1, the protection window 31 may be inserted in a hole (not referenced), which is formed in the tray 33. Alternatively, unlike illustrated in FIG. 1, the protection window 31 may be placed on the hole formed in the tray 33.

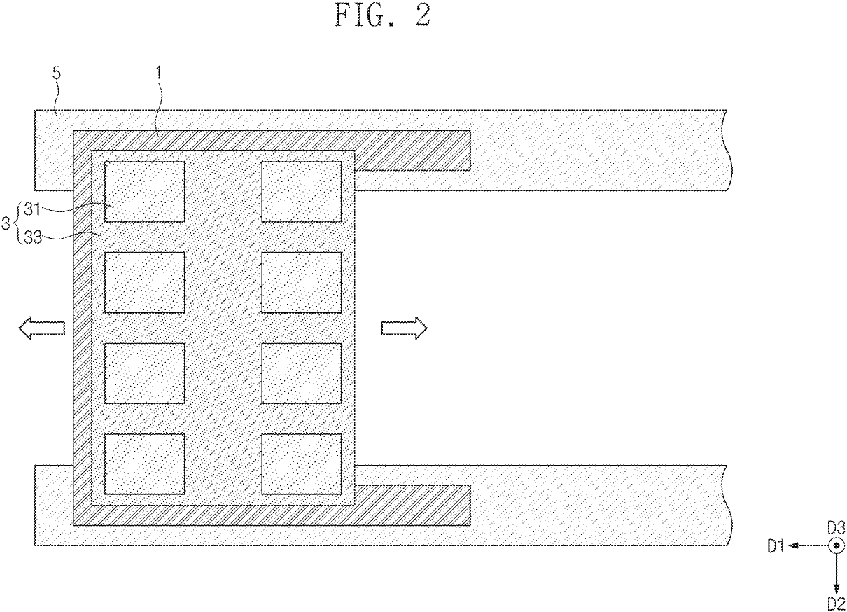

The shuttle 1 may support the protection window assembly 3. The shuttle 1 may be configured to move the protection window assembly 3 in a horizontal direction. This will be described in greater detail with reference to FIG. 2.

The linear motion unit 5 may support the shuttle 1. The linear motion unit 5 may be configured to move the shuttle 1 in the first direction D1 and/or the opposite direction of the first direction D1. In an embodiment, the linear motion unit 5 may include a delivery unit, such as a conveyer belt. In an embodiment, the linear motion unit 5 may include a steel belt, which is extended in the first direction D1. In such an embodiment, as the steel belt is moved along a closed loop enclosing a pulley unit, the shuttle 1 on the linear motion unit 5 may be moved in the first direction D1 and/or the opposite direction of the first direction D1. The linear motion unit 5 may be configured to prevent the protection window 31 from being moved in the second direction D2 and/or the third direction D3. In such an embodiment, by using the linear motion unit 5, the protection window 31 may be configured to be movable in only the first direction D1 and/or the opposite direction of the first direction D1.

The output adjustment unit 4 may adjust an output of the laser beam emitted from the laser module 2. In an embodiment, for example, the output adjustment unit 4 may include a diaphragm, which is used to control an output of the laser beam emitted from the laser module 2. The output adjustment unit 4 may be located between the laser module 2 and the protection window 31. In an embodiment where a plurality of laser modules 2 are provided, a plurality of output adjustment units 4 may be provided. Hereinafter, for convenience in description, embodiments, in which a single output adjustment unit 4 is provided, will be described in detail.

The position sensor 6 may sense a position of the protection window 31. In an embodiment, for example, the position sensor 6 may be configured to sense a position of the protection window assembly 3 and/or the shuttle 1 and to calculate a position of the protection window 31. In such an embodiment, the position sensor 6 may include an infrared distance sensor or the like, but the invention is not limited to this example. In an embodiment, two or more position sensors 6 may be provided. The position sensors 6 may be spaced apart from each other in the first direction D1. Accordingly, motion of the protection window 31 in the first direction D1 may be more accurately sensed by the position sensor 6. Hereinafter, for convenience in description, embodiments, in which a single position sensor 6 is provided, will be described in detail.

The protection window replacement chamber C2 may be connected to the laser etching chamber C1. The protection window replacement chamber C2 may define a replacement space C2h. The replacement space C2h may be connected to the etching space C1h through a second door G2. In addition, the replacement space C2h may be selectively connected to an outer space through a third door G3. The replacement space C2h may be connected to the second vacuum pump VP2. By using the second vacuum pump VP2, the replacement space C2h may be in a vacuum state, when a fabrication process is performed.

The protection window storing stage 9 may be placed in the protection window replacement chamber C2. The protection window storing stage 9 may be used to store one or more preliminary protection window assemblies 3p. In addition, the protection window storing stage 9 may be used to store a protection window assembly 3 used in a previous process.

The first vacuum pump VP1 may be connected to the laser etching chamber C1. The etching space C1h may be in a vacuum state by a vacuum pressure exerted from the first vacuum pump VP1.

The second vacuum pump VP2 may be connected to the protection window replacement chamber C2. The replacement space C2h may be in a vacuum state by a vacuum pressure exerted from the second vacuum pump VP2.

The control unit CR may be configured to control the laser module 2 and the linear motion unit 5. The control unit CR may control the linear motion unit 5, based on information on a position of the protection window 31 provided from the position sensor 6. In addition, the control unit CR may control the laser module 2 and/or the output adjustment unit 4, based on information on an output of the laser beam provided from the output sensing unit 8. This will be described in greater detail below.

FIG. 2 is a plan view illustrating a portion of a laser etching apparatus according to an embodiment of the invention.

Referring to FIG. 2, in an embodiment, two linear motion units 5 may be provided. The two linear motion units 5 may be spaced apart from each other in the second direction D2. The shuttle 1 may be placed on the two linear motion units 5. The shuttle 1 may be moved in the first direction D1 and/or the opposite direction of the first direction D1 by rotation of the two linear motion units 5.

The protection window assembly 3 may be placed on the shuttle 1. In an embodiment, a plurality of protection windows 31 may be provided. The plurality of protection windows 31 may be spaced apart from each other in the first and second directions D1 and D2.

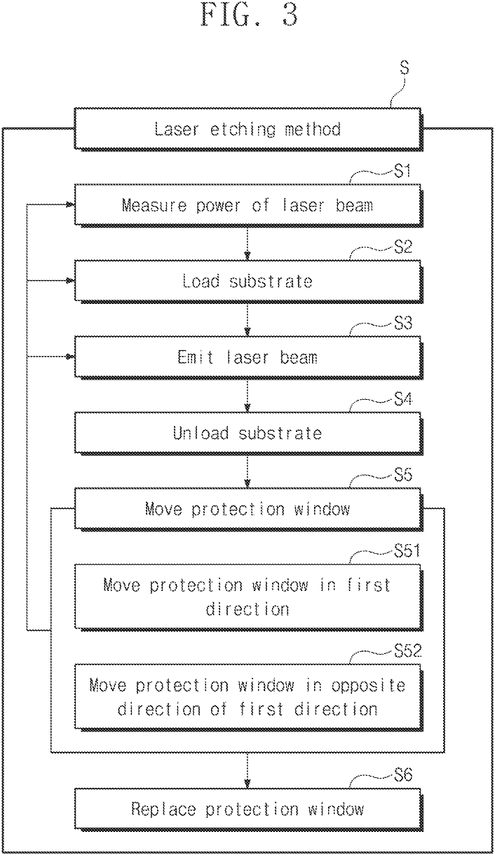

FIG. 3 is a flow chart illustrating a laser etching method according to an embodiment of the invention.

In FIG. 3, an embodiment of a laser etching method (S) is shown. The laser etching method (S) may be a method of etching a substrate using the laser etching apparatus A described with reference to FIGS. 1 and 2. The laser etching method (S) may include a process (S1) of measuring a power of a laser beam, a process (S2) of loading a substrate, a process (S3) of emitting a laser beam, a process (S4) of unloading the substrate, a process (S5) of moving a protection window, and a process (S6) of replacing the protection window.

The process (S5) of moving the protection window may include a process (S51) of moving the protection window in a first direction and a process (S52) of moving the protection window in a direction opposite to the first direction.

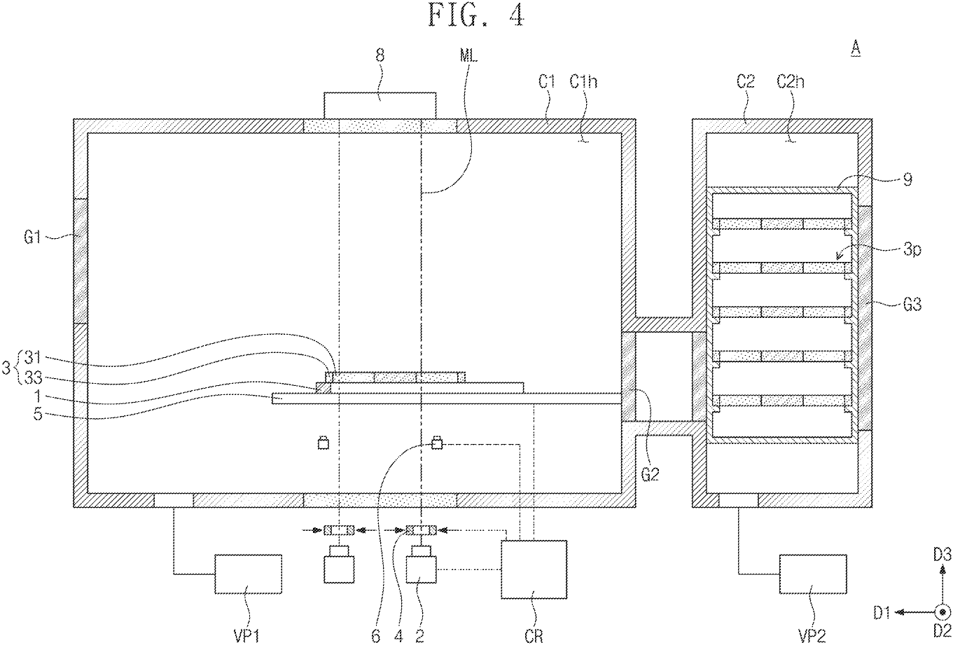

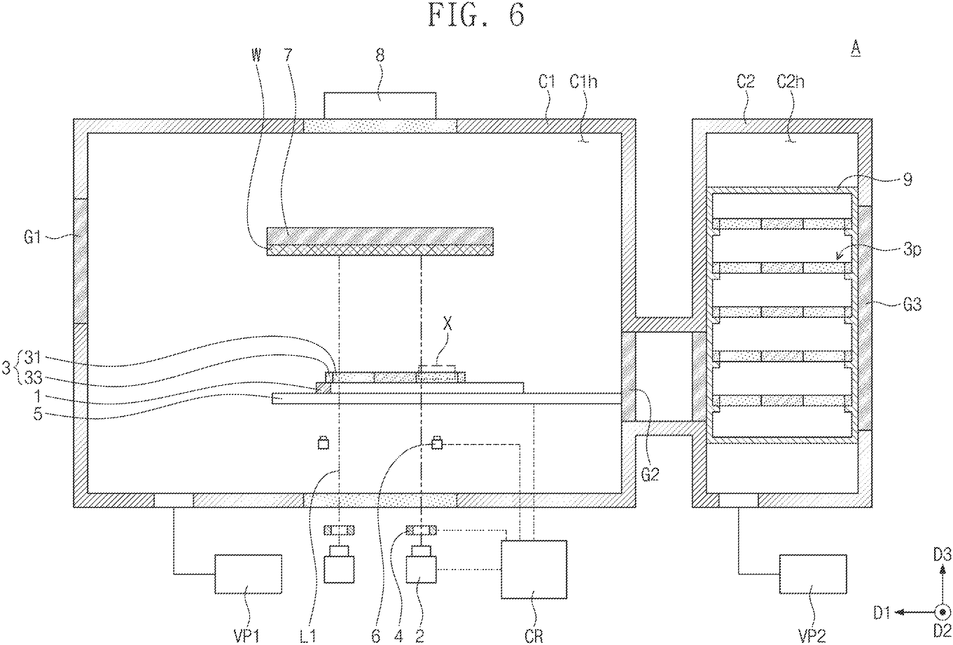

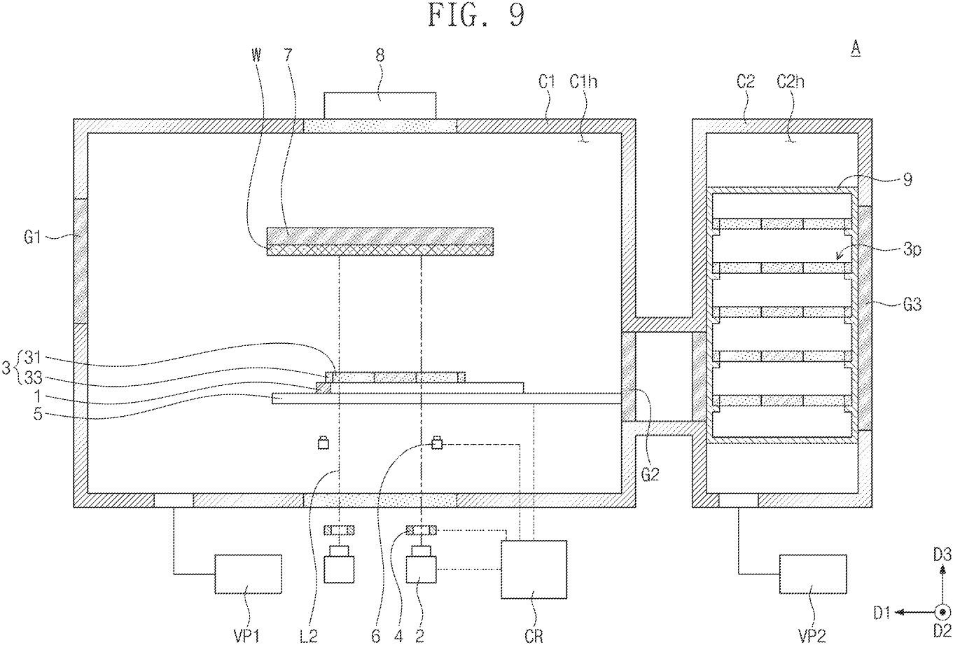

Hereinafter, each process in the laser etching method (S) of FIG. 3 will be described in greater detail with reference to FIGS. 4 to 17.

FIGS. 4 to 17 are diagrams sequentially illustrating processes of the laser etching method shown in the flow chart of FIG. 3.

Referring to FIGS. 4 and 3, the process (S1) of measuring an output power of the laser beam may include emitting a measurement laser ML from the laser module 2 toward the output sensing unit 8 through the protection window 31, in a state where the chuck 7 (e.g., the chuck 7 of FIG. 1) is not provided. Accordingly, the control unit CR may obtain information on an output power of the laser beam, which is emitted from the laser module 2 and passes through the protection window 31, when the chuck 7 is not provided. The control unit CR may control the output adjustment unit 4 such that the output power of the laser beam is within a desired range. In an embodiment, for example, an opened area of a diaphragm may be adjusted by the control unit CR, and in this case, the output adjustment unit 4 and/or the laser module 2 may be controlled in a way such that the output power of the laser beam passed through the protection window 31 has a specific value.

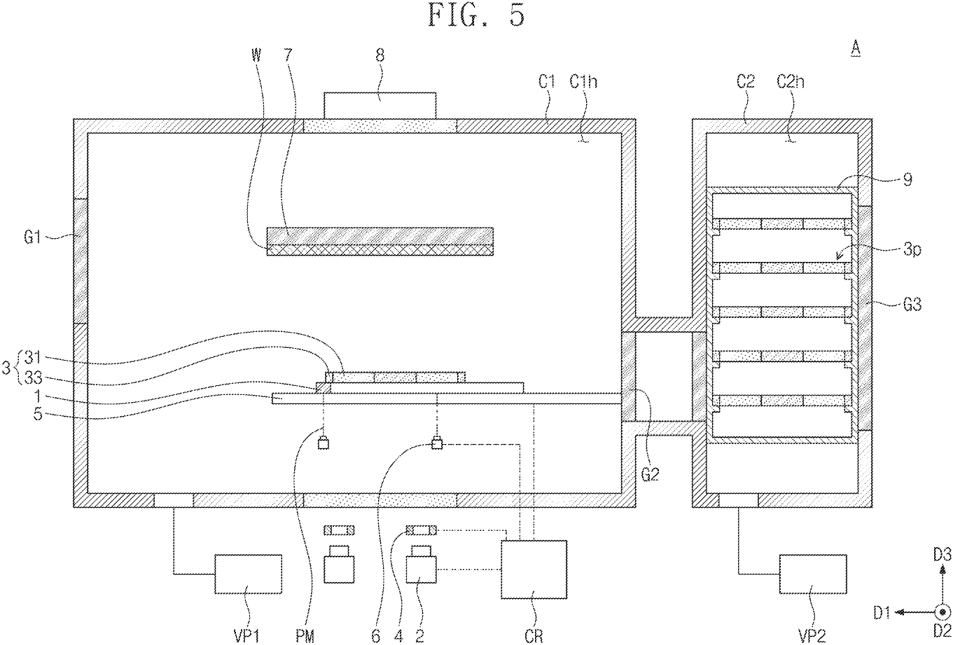

Referring to FIGS. 5 and 3, the process (S2) of loading the substrate may include placing a substrate W on the laser module 2 using the chuck 7. The substrate W may be fastened to the chuck 7. The substrate W may include a substrate requiring a laser etching process. In an embodiment, for example, the substrate W may include a display device. In such an embodiment, the substrate W may include an organic light-emitting display device including a deposited organic layer. A hole may be formed in the organic layer of the substrate W by the laser etching apparatus A. However, the invention is not limited to this example, and in an alternative embodiment, the substrate W may be a semiconductor wafer.

The position sensor 6 may sense a position of the protection window 31. In an embodiment, for example, a current position of the protection window 31 may be examined by a position sensing infrared light PM, which is emitted from the position sensor 6.

Referring to FIGS. 6, 7, and 3, the process (S3) of emitting the laser beam may include a first emission process of emitting a laser beam from the laser module 2 toward the substrate W. The laser beam emitted from the laser module 2 in the first emission process may be referred to as a first laser L1. The first laser L1 may pass through the protection window 31 and may be incident into a bottom surface of the substrate W. A specific region of the substrate W may be etched by the first laser L1. Particles may be produced during the process of etching the substrate W. Due to the gravity, the particle may fall in a downward direction. The downwardly-falling particle may be captured on a top surface 31u of the protection window 31. If an etching process is performed when the substrate W, the laser module 2, and the protection window 31 are fixed to specific positions, a particle, which is produced from a specific region of the substrate W, may be piled up on a specific region of the protection window 31. In an embodiment, for example, on the top surface 31u of the protection window 31, the particle may form a first capture particle Pa1, as illustrated in FIG. 7. The first capture particle Pa1 may be a particle group, which is formed by capturing particles produced during the first emission process. The first capture particle Pa1 may have a height that is high on a propagation path of the first laser L1 and is gradually lowered as a distance from the path increases. In an embodiment, for example, the first capture particle Pa1 may form a Gaussian distribution. A height of the first capture particle Pa1 may be referred to as a first height h1. The first height h1 may be several micrometers to several hundreds of micrometers, but the invention is not limited to this example.

Referring back to FIG. 3, the process (S4) of unloading the substrate may include unloading the substrate W from the chuck 7. In an embodiment, before the movement of the protection window 31, an etching process on one substrate W may be finished, and then, the substrate W may be unloaded from the laser etching apparatus A. However, the invention is not limited to this example, and in an alternative embodiment, the process (S5) of moving the protection window 31 may be performed during the etching process on one substrate W. Hereinafter, for convenience in description, embodiments, in which the process (S5) of moving the protection window 31 is performed during the etching process on the substrate W, will be described in detail.

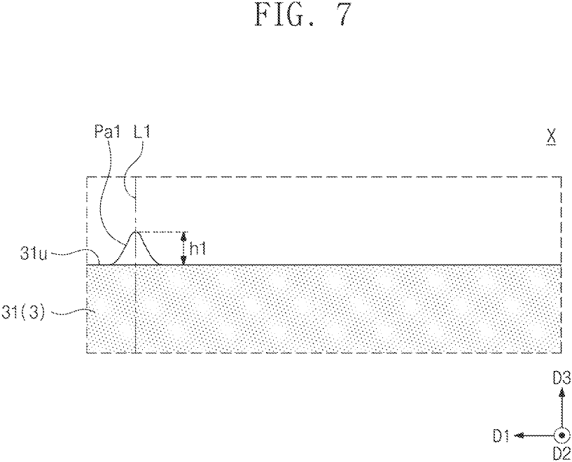

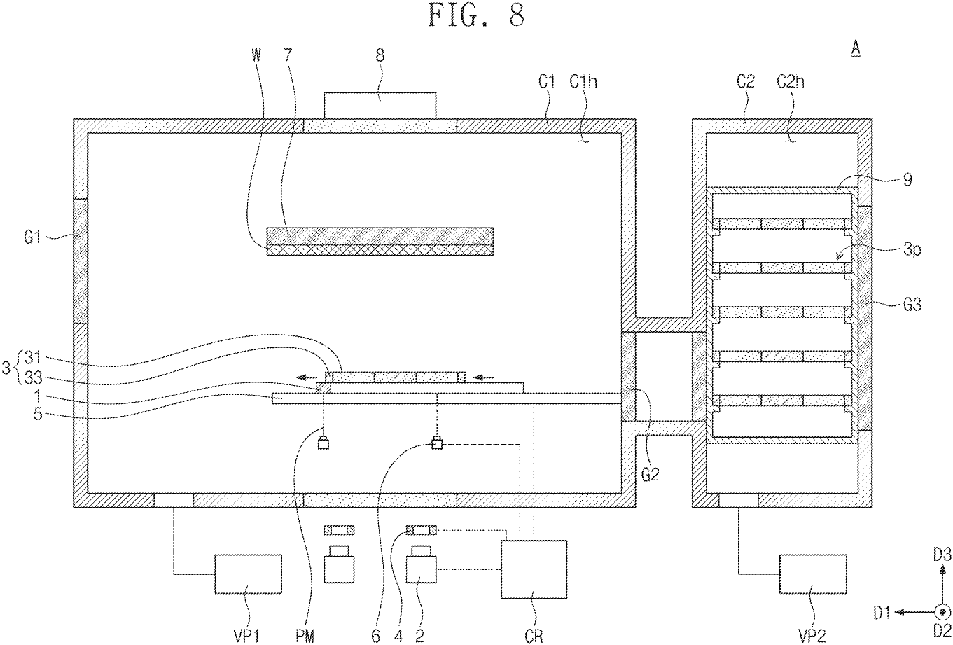

Referring to FIGS. 8 and 3, the process (S51) may include moving the protection window assembly 3 in the first direction D1 using the linear motion unit 5. In this process, the moving distance of the protection window 31 in the first direction D1 may be referred to as a first distance. In such an embodiment, the process (S51) of moving the protection window in the first direction may include a process of moving the protection window 31 in the first direction D1 by a first distance. This will be described in greater detail below.

Referring to FIGS. 9, 10, and 3, after the process of moving the protection window 31 in the first direction D1 by the first distance, a process (S2) of emitting a laser beam may be performed again. The process (S2) of emitting the laser beam may include a second emission process of emitting a laser beam from the laser module 2 toward the substrate W. The laser beam emitted from the laser module 2 in the second emission process may be referred to as a second laser L2. The second laser L2 may pass through the protection window 31 and may be incident into the bottom surface of the substrate W. A specific region of the substrate W may be etched by the second laser L2. Particles may be produced during the process of etching the substrate W. Due to the gravity, the particle may fall in a downward direction. The downwardly-falling particle may be captured on a top surface 31u of the protection window 31. The particles on the top surface 31u of the protection window 31 may form a second capture particle Pa2. The second capture particle Pa2 may be a particle group, which is formed by capturing particles produced during the second emission process. The second capture particle Pa2 may form the Gaussian distribution. A height of the second capture particle Pa2 may be referred to as a second height h2. The second height h2 may be substantially equal or similar to the first height h1, but the invention is not limited to this example.

Since, in the process (S5) of moving the protection window, the protection window 31 is moved by the first distance, the second capture particle Pa2 may be spaced apart from the first capture particle Pa1 in the opposite direction of the first direction D1 by a first distance w1. In such an embodiment, a center axis of the first capture particle Pa1 may be spaced apart from a center axis of the second capture particle Pa2 in the first direction D1 by the first distance w1. The first distance w1 may be in a range from about 1 millimeter (mm) to about 10 mm. In an embodiment, for example, the first distance w1 may be about 5 mm.

In an embodiment, as described above, the first and second emission processes may be performed on a same substrate W, but the invention is not limited to this example. In an embodiment, as described above, before the process of moving the protection window 31 in the first direction D1 by the first distance w1, a substrate, which is etched in the first emission process, may be removed from the laser etching apparatus A, and a new substrate may be loaded on the chuck 7. In this case, a substrate to be etched in the second emission process may be different from the substrate etched in the first emission process.

Referring to FIGS. 11 and 3, the process (S3) of emitting the laser beam (may be referred to as a first emission process) and the process (S51) of moving the protection window in the first direction may be sequentially repeated (e.g., n times) to form a plurality of first capture particles Pa1, Pa2, ..., and Pan on the top surface 31u of the protection window 31. The capture particles Pa1, Pa2, ..., and Pan may be spaced apart from each other in the first direction D1. Here, the first emission process performed to form a first first capture particle Pa1 may be referred to as a first first emission process, and the first emission process performed to form a n-th first capture particle Pan may be referred to as an n-th first emission process.

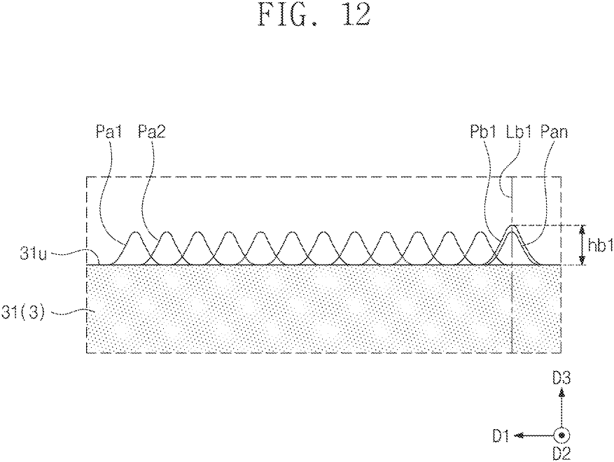

Referring to FIGS. 12 and 3, the process (S3) of emitting the laser beam may include a first second emission process (hereinafter, will be referred to as “(2-1)-th emission process”) of emitting a laser beam from the laser module 2 toward the substrate W. The laser beam emitted from the laser module 2 in the (2-1)-th emission process may be referred to as a first second laser (hereinafter, will be referred to as “(2-1)-th laser”) Lb1. A relative position between the protection window 31 and the laser module 2 in the (2-1)-th emission process may be the same as a relative position between the protection window 31 and the laser module 2 in an n-th first emission process. Thus, the (2-1)-th laser Lb1 may pass through the protection window 31 and the n-th first capture particle Pan and may be incident into the bottom surface of the substrate W. A specific region of the substrate W may be etched by the (2-1)-th laser Lb1. Particles may be produced during the process of etching the substrate W. Due to the gravity, the particle may fall in a downward direction. The downwardly-falling particle may be captured on a top surface 31u of the protection window 31. The particles on the top surface 31u of the protection window 31 may form a first second capture particle (hereinafter, will be referred to as “(2-1)-th capture particle”) Pb1. The (2-1)-th capture particle Pb1 may be piled up on the n-th first capture particle Pan. A height of the (2-1)-th capture particle Pb1 may be referred to as a first second height (hereinafter, will be referred to as “(2-1)-th height”) hb1. The (2-1)-th height hb1 may be larger than the first height h1.

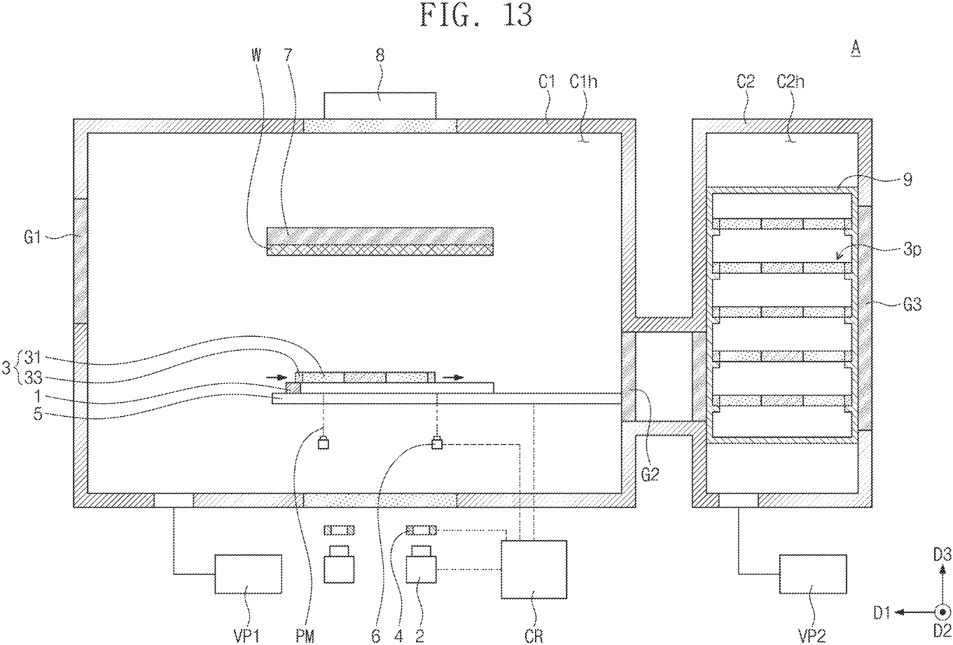

Referring to FIGS. 13 and 3, the process (S52) of moving the protection window in the direction opposite to the first direction may include moving the protection window assembly 3 in the opposite direction of the first direction D1 using the linear motion unit 5. In this process, a moving distance of the protection window 31 in the opposite direction of the first direction D1 may be referred to as a second distance. In such an embodiment, the process (S51) may include moving the protection window 31 in the opposite direction of the first direction by the second distance. This will be described in greater detail below.

Referring to FIGS. 14, 15, and 3, the process (S3) of emitting the laser beam may include a second second emission process (hereinafter, will be referred to as “(2-2)-th emission process”) of emitting a laser beam from the laser module 2 toward the substrate W. The laser beam emitted from the laser module 2 in the (2-2)-th emission process may be referred to as a second second laser (hereinafter, will be referred to as “(2-2)-th laser”) Lb2.

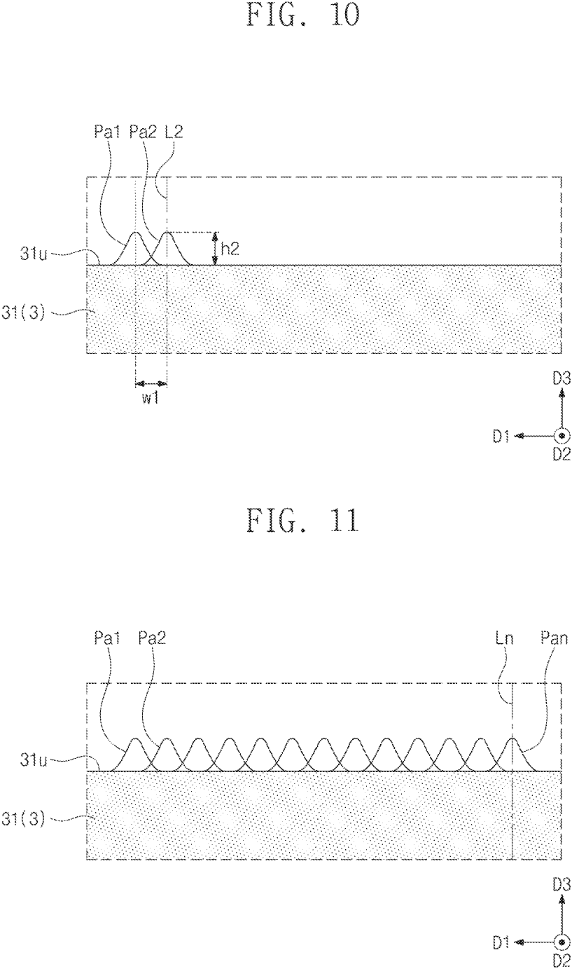

Since, in the process (S5) of moving the protection window, the protection window 31 is moved by the second distance, a second second capture particle (hereinafter, will be referred to as “(2-2)-th capture particle”) Pb2 may be spaced apart from the (2-1)-th capture particle Pb1 in the first direction D1 by the second distance w2. The second distance w2 may be substantially equal or similar to the first distance w1 (e.g., of FIG. 10). That is, a relative position between the protection window 31 and the laser module 2 in the (2-2)-th emission process may be the same as a relative position between the protection window 31 and the laser module 2 in the (n-1)-th first emission process. Thus, the (2-2)-th laser Lb2 may pass through the protection window 31 and an (n-1)-th first capture particle Pa(n-1) and may be incident into the bottom surface of the substrate W. A specific region of the substrate W may be etched by the (2-2)-th laser Lb2. Particles may be produced during the process of etching the substrate W. Due to the gravity, the particle may fall in a downward direction. The downwardly-falling particle may be captured on a top surface 31u of the protection window 31. On the top surface 31u of the protection window 31, the particles may form the (2-2)-th capture particle Pb2. The (2-2)-th capture particle Pb2 may be piled up on the (n-1)-th first capture particle Pa(n-1).

Referring to FIGS. 16 and 3, the process (S3) of emitting the laser beam and the process (S52) of moving the protection window in the direction opposite to the first direction may be sequentially repeated (e.g., n times) to form a plurality of second capture particles (Pbn and so forth) on the top surface 31u of the protection window 31. The capture particles (Pbn and so forth) may be spaced apart from each other in the first direction D1.

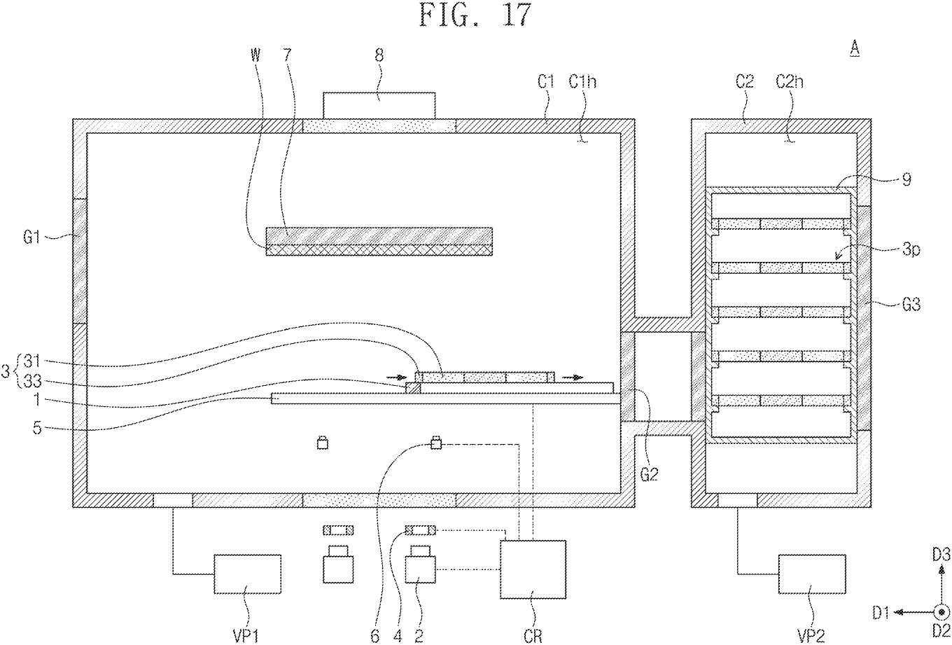

Referring to FIGS. 17 and 3, the process (S6) of replacing the protection window assembly 3 may be performed when the process (S3) of emitting the laser beam executes a predetermined number of times. In an embodiment, the protection window assembly 3 on the shuttle 1 may be moved by the linear motion unit 5 and may be loaded on the protection window storing stage 9. One of the preliminary protection window assemblies 3p may be loaded on the shuttle 1 and then may be moved into the laser etching chamber C1.

In a laser etching apparatus according to an embodiment of the invention and a laser etching method using the laser etching apparatus, the protection window may be frequently moved during the laser etching process in a way such that particles are uniformly captured on a wide region of the protection window. Thus, particles may be effectively prevented from being highly piled up on a specific region of the protection window such that a replacement period of the protection window may be increased.

In a laser etching apparatus according to an embodiment of the invention and a laser etching method using the laser etching apparatus, due to the frequent movement of the protection window, a height of particles, which are piled up on the protection window, may be relatively uniform. Thus, the output of the laser beam may be uniform, regardless of a position of the laser beam emitted to the piled particles. Accordingly, cost and time for a process of adjusting the output power of the laser beam may be reduced.

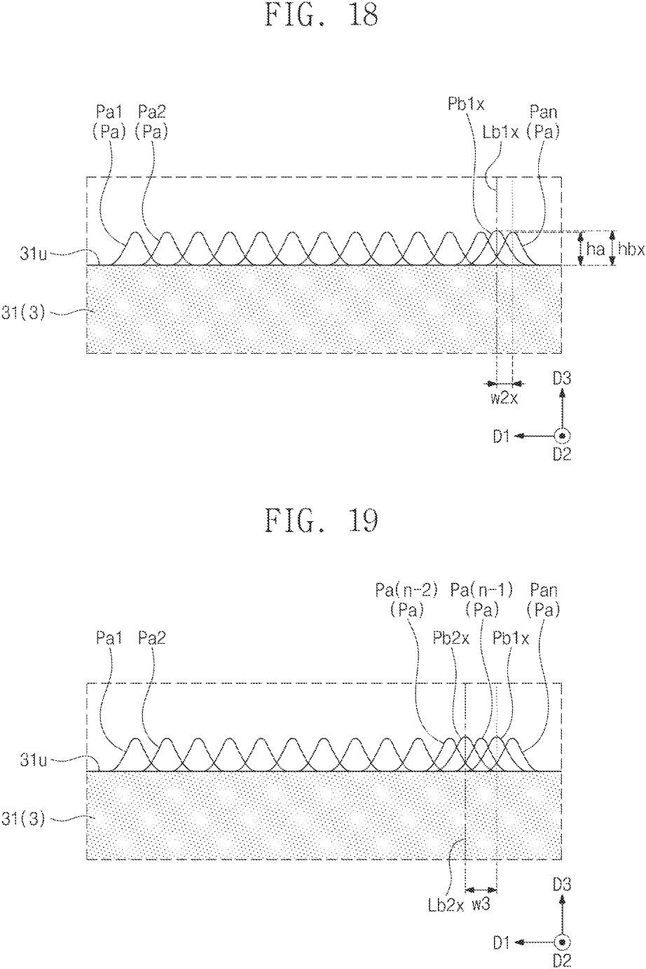

FIGS. 18 and 19 are diagrams sequentially illustrating processes of the laser etching method shown in the flow chart of FIG. 3.

In the following description, for concise description, the same or like elements as those described above with reference to FIGS. 1 to 17 may be labeled with the or like same reference numbers, and any repetitive detailed description thereof will be omitted.

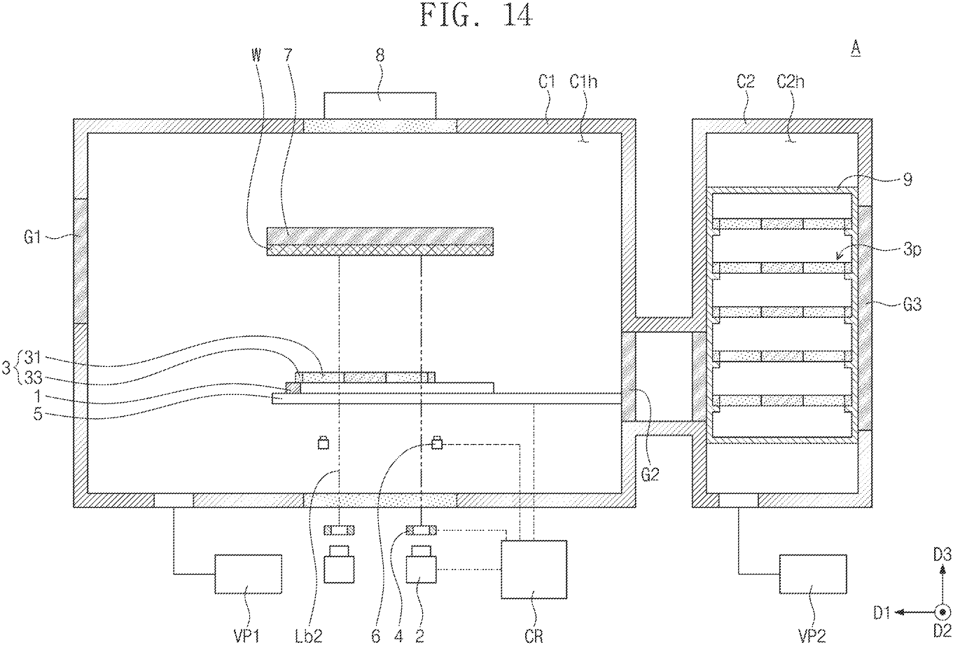

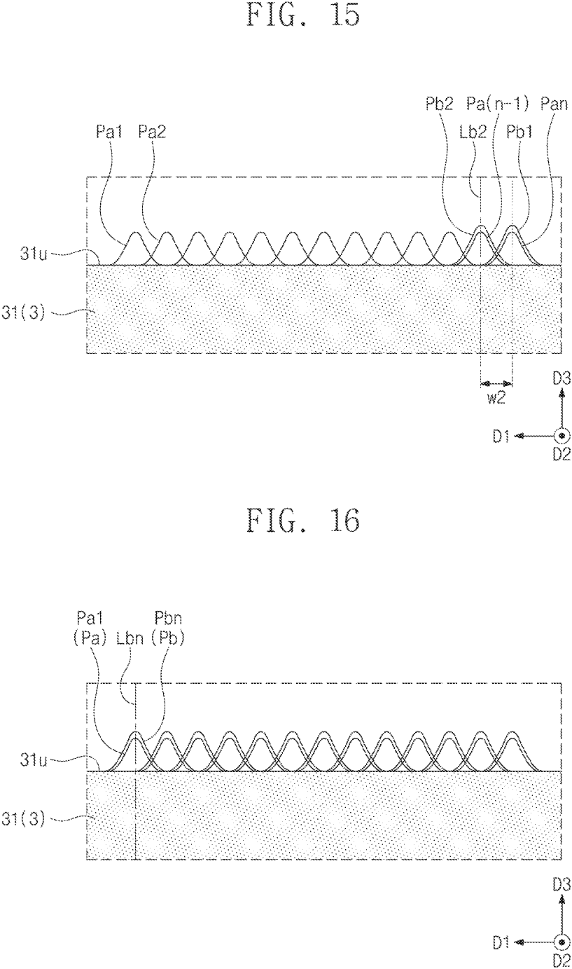

Referring to FIG. 18, in an embodiment, a second distance w2x may be smaller than the first distance w1 (e.g., of FIG. 10), unlike the embodiment of FIG. 15. In an embodiment, for example, the second distance w2x may be about half of the first distance w1. Thus, an (2-1)-th capture particle Pb1x may be placed between the n-th first capture particle Pan and the (n-1)-th first capture particle Pa(n-1). In such an embodiment, a new particle may be captured between two adjacent first capture particles, which are previously piled up and are adjacent to each other. A height of the (2-1)-th capture particle Pb1x may be referred to as a second height hbx. In an embodiment, as shown in FIG. 18, the second height hbx may be substantially equal to or greater than a first height ha. However, the second height hbx of FIG. 18 may be smaller than that in the embodiment described with reference to FIG. 12.

Referring to FIGS. 19 and 3, the process (S52) of moving the protection window in the direction opposite to the first direction may include a process of moving the protection window 31 in the opposite direction of the first direction D1 by a third distance w3. The third distance w3 may be substantially equal or similar to the first distance w1 (e.g., of FIG. 10).

In a laser etching apparatus according to an embodiment of the invention and a laser etching method using the laser etching apparatus, a new particle may be captured between two adjacent first capture particles, which are previous piled and are adjacent to each other a process. In an embodiment, for example, the new particle may be captured at a center of an axis of each of the two adj acent first capture particles. Thus, a height of a newly-piled particle may be relatively low. Thus, an output of the laser beam passing through a previously-piled particle may be maintained to a specific level or higher. Accordingly, a replacement period of the protection window may be increased.

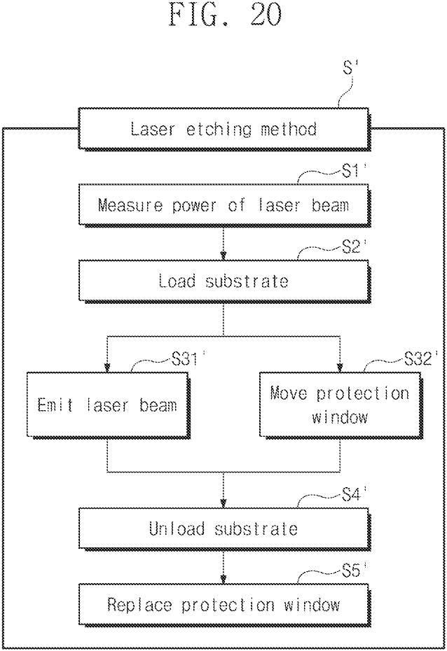

FIG. 20 is a flow chart illustrating a laser etching method according to an embodiment of the invention.

Referring to FIG. 20, an embodiment of a laser etching method (S′) may include a process (S1′) of measuring power of a laser beam, a process (S2′) of loading a substrate, a process (S31′) of emitting a laser beam, a process (S32′) of moving a protection window, a process (S4′) of unloading the substrate, and a process (S5′) of replacing the protection window.

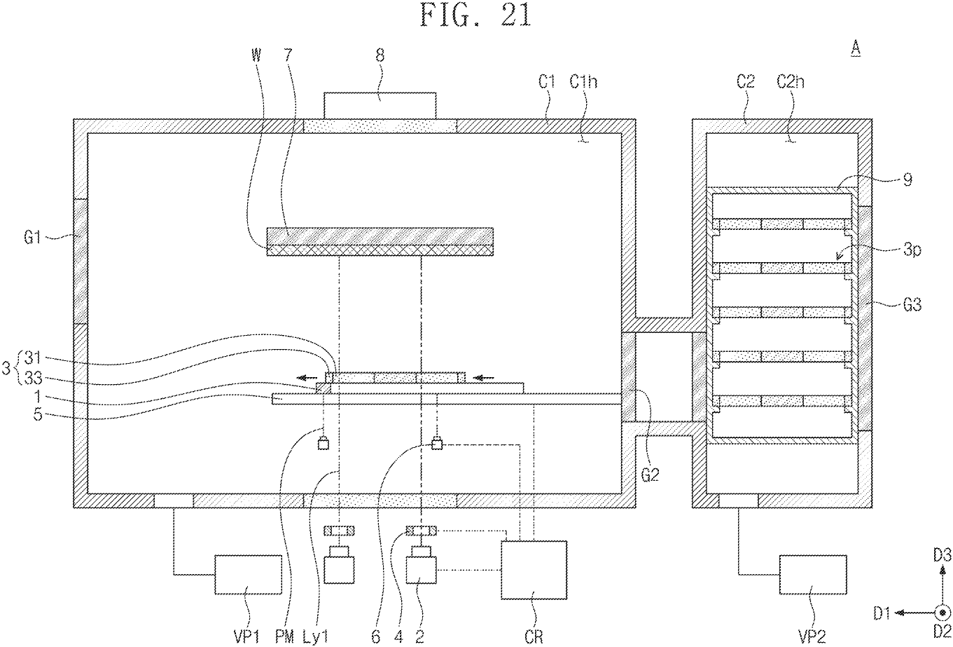

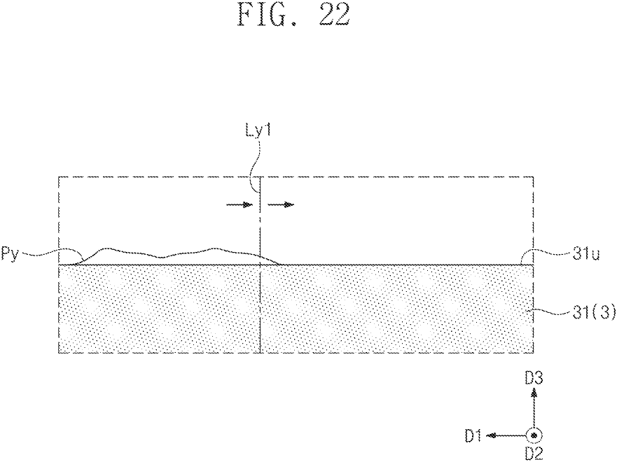

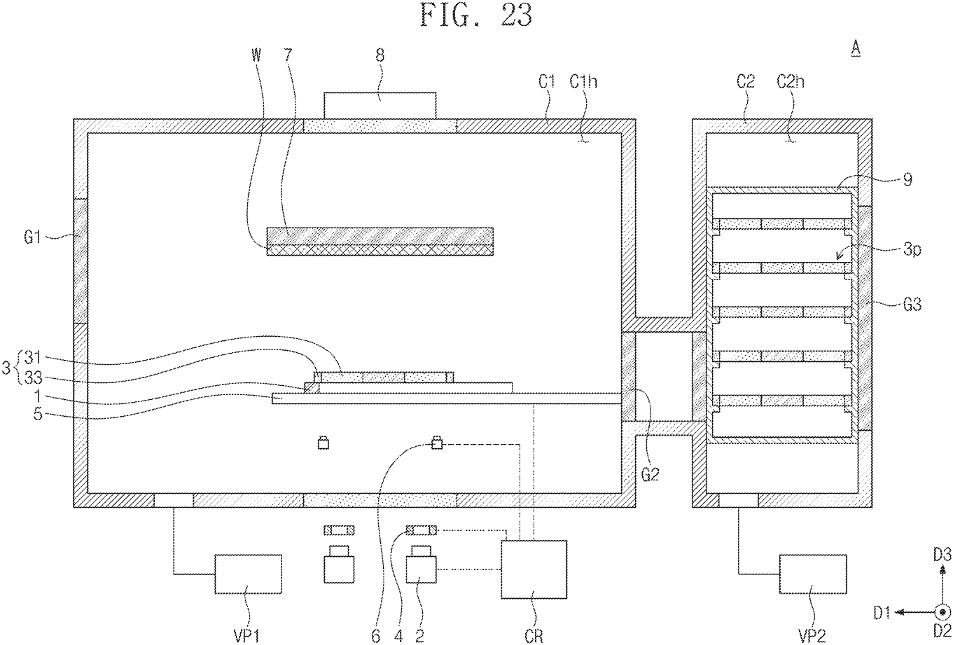

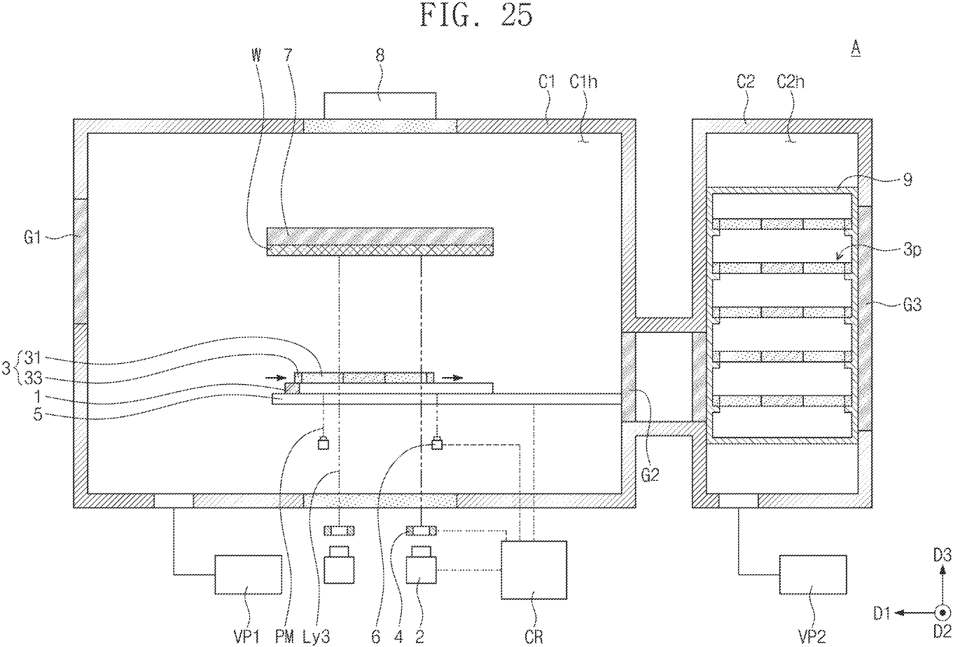

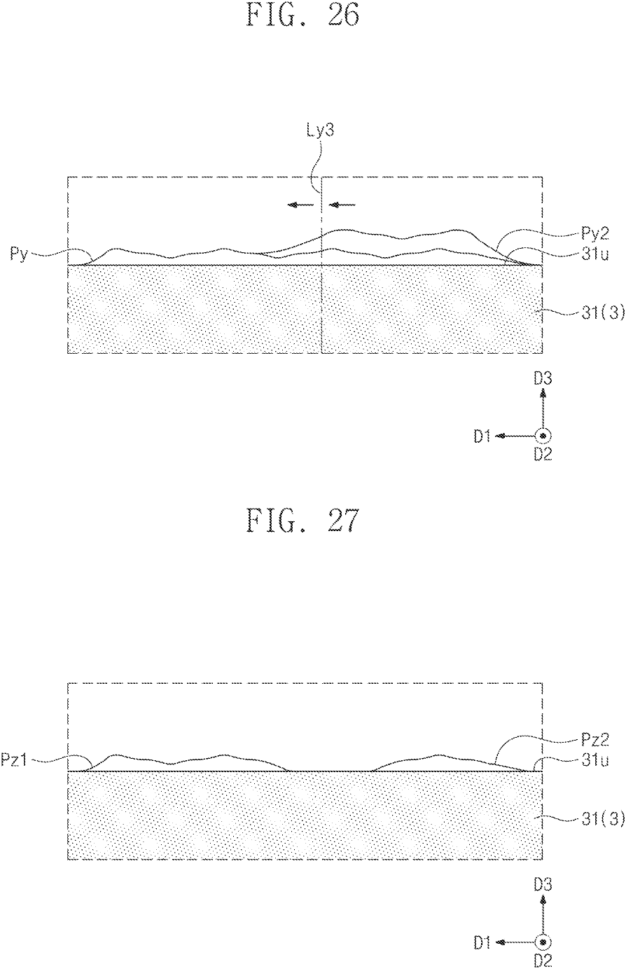

Hereinafter, processes in the laser etching method (S′) of FIG. 20 will be sequentially described with reference to FIGS. 21 to 26.

FIGS. 21 to 26 are diagrams sequentially illustrating processes of the laser etching method shown in the flow chart of FIG. 20.

In the following description, for concise description, the same or like elements as those described with reference to FIGS. 1 to 19 may be labeled with the same or like reference numbers, and any repetitive detailed description thereof will be omitted.

Referring to FIGS. 21, 22, and 20, the process (S31′) of emitting the laser beam may include a first emission process of emitting a laser beam Ly1 from the laser module 2 toward the substrate W. At the same time, the process (S32′) of moving the protection window may be performed. In such an embodiment, during the first emission process of the laser beam Ly1, the protection window 31 may be moved. In an embodiment, for example, during the first emission process of the laser beam Ly1, the protection window 31 may be moved in the first direction D1. Thus, particles may be uniformly piled up on the top surface 31u of the protection window 31. In such an embodiment, unlike illustrated in FIG. 7, first capture particles Py may be uniformly formed throughout a wide region on the protection window 31.

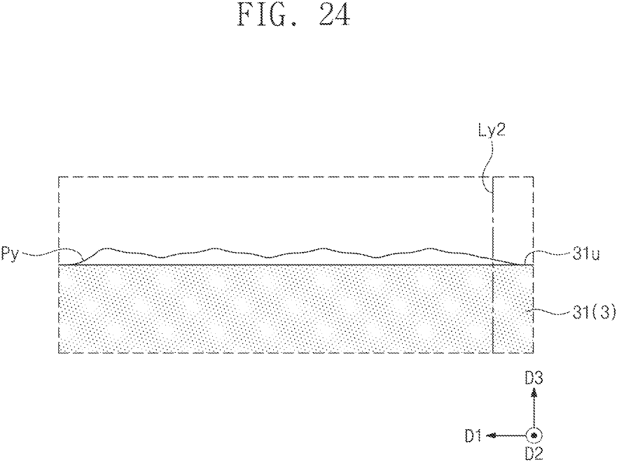

Referring to FIGS. 23, 24, and 20, the laser etching method (S′) may further include a process of interrupting the emission of the laser beam, after the first emission process. The emission of the laser beam from the laser module 2 may be stopped. The process (S32′) of moving the protection window may be terminated in the process of stopping the emission of the laser beam. In such an embodiment, in the process of stopping the emission of the laser beam, the protection window 31 may be at rest. When the emission of the laser beam is restarted, the protection window 31 may be moved again. Thus, as illustrated in FIG. 24, particles may be uniformly distributed on the entire region of the protection window 31.

Referring to FIGS. 25, 26, and 20, the process (S32′) of moving the protection window may further include a process of moving the protection window 31 in the opposite direction of the first direction D1. In such an embodiment, the protection window 31 may be moved in the first direction D1 by a specific distance, and then, may be moved in the opposite direction of the first direction D1. Thus, a second capture particle Py2 may be formed on the first capture particle Py. The specific distance may be in a range from about 40 mm to about 120 mm. In an embodiment, for example, the specific distance may be about 80 mm. However, the invention is not limited to this example, and a detailed value may be changed depending on desired technical features.

In a laser etching apparatus according to an embodiment of the invention and a laser etching method using the laser etching apparatus, a protection window may be moved during an etching process using a laser beam. Thus, particles may be uniformly piled up on a wide region of a protection window. Accordingly, uniformity of an output power of the laser beam may be improved, and a replacement period of the protection window may be increased.

FIG. 27 is a diagram illustrating the laser etching method shown in the flow chart of FIG. 20.

In the following description, for concise description, the same or like elements as those described with reference to FIGS. 1 to 26 may be labeled by the same or like reference numbers, and any repetitive detailed description thereof will be omitted.

Referring to FIGS. 27 and 20, the process (S32′) of moving the protection window may be continued during the process of stopping the emission of the laser beam. That is, the protection window 31 may be ceaselessly moved during the process of stopping the emission of the laser beam. Accordingly, as illustrated in FIG. 27, a plurality of capture particles Pz1 and Pz2 may be disposed on the top surface 31u of the protection window 31 to be spaced apart from each other.

In a laser etching apparatus according to an embodiment of the invention and a laser etching method using the laser etching apparatus, a replacement period of a protection window may be increased, thereby reducing fabrication cost and process time.

In a laser etching apparatus according to an embodiment of the invention and a laser etching method using the laser etching apparatus, particles are uniformly dispersed, such that a laser beam is allowed to have uniform power.

In a laser etching apparatus according to an embodiment of the invention and a laser etching method using the laser etching apparatus, time for a process of controlling a diaphragm to adjust the power of the laser beam may be reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A laser etching method, comprising:
performing a first emission process by emitting a laser beam from a laser module toward a substrate fastened to a chuck in a laser etching chamber;
moving a protection window between the chuck and the laser module in a first direction by a first distance after the performing the first emission process;
performing a second emission process by emitting a laser beam from the laser module after the moving the protection window in the first direction by the first distance;
moving the protection window in an opposite direction of the first direction by a second distance after the performing the second emission process; and
performing a third emission process by emitting a laser beam from the laser module after the moving the protection window in the opposite direction of the first direction by the second distance.

2. The laser etching method of claim 1, wherein
the second distance is equal to the first distance, and
a relative position between the laser module and the protection window in the first emission process is equal to a relative position between the laser module and the protection window in the third emission process.

3. The laser etching method of claim 1, wherein the second distance is smaller than the first distance.

4. The laser etching method of claim 3, wherein the second distance is half of the first distance.

5. The laser etching method of claim 3, further comprising:
moving the protection window in the opposite direction of the first direction by a third distance after the performing the third emission process; and
performing a fourth emission process by emitting a laser beam from the laser module after the moving the protection window in the opposite direction of the first direction by the third distance,
wherein the third distance is the same as the first distance.

6. The laser etching method of claim 1, wherein the first distance is in a range from about 1 mm to about 10 mm.

7. The laser etching method of claim 1, further comprising:
replacing the protection window after an emission of the laser beam from the laser module is executed a predetermined number of times.

8. The laser etching method of claim 1, further comprising:
unloading the substrate fastened to the chuck, before the moving the protection window in the first direction by the first distance and after the performing the first emission process.

9. The laser etching method of claim 1, further comprising:
measuring a power of the laser beam emitted from the laser module, before the performing the first emission process.

10. A laser etching method, comprising:
loading a substrate in a laser etching apparatus;
performing a first emission process by emitting a laser beam from a laser module toward the substrate; and
moving a protection window between the substrate and the laser module, during the performing the first emission process.

11. The laser etching method of claim 10, wherein the moving the protection window comprises:
moving the protection window in a first direction; and
moving the protection window in an opposite direction of the first direction, when the protection window is moved in the first direction by a specific distance.

12. The laser etching method of claim 11, wherein the specific distance is in a range from about 40 mm to about 120 mm.

13. The laser etching method of claim 10, further comprising:
stopping an emission of the laser beam after the performing the first emission process.

14. The laser etching method of claim 13, wherein the moving the protection window is finished after the performing the first emission process such that the protection window is at rest during the stopping the emission of the laser beam.

15. The laser etching method of claim 13, wherein the moving the protection window is continued after the first emission process such that the protection window is ceaselessly moved during the stopping the emission of the laser beam.

16. A laser etching apparatus, comprising:
a laser etching chamber;
a chuck disposed in the laser etching chamber;
a laser module which emits a laser beam toward the chuck;
a protection window between the chuck and the laser module;
a tray which supports the protection window;
a linear motion unit which moves the tray in a first direction; and
a position sensor which senses a position of the protection window.

17. The laser etching apparatus of claim 16, wherein the laser module is placed below the protection window.

18. The laser etching apparatus of claim 16, wherein the linear motion unit comprises a steel belt which extends in the first direction.

19. The laser etching apparatus of claim 16, further comprising:
a control unit which controls the laser module and the linear motion unit,
wherein the control unit controls the linear motion unit to move the protection window in the first direction or an opposite direction of the first direction, between processes of emitting the laser beam from the laser module.

20. The laser etching apparatus of claim 16, further comprising:
a control unit which controls the laser module and the linear motion unit,
wherein the control unit controls the linear motion unit to move the protection window in the first direction or an opposite direction of the first direction, during a process of emitting the laser beam from the laser module.
